(19) United States
(12) Patent Application Publication
(10) Pub. No.: US 2015/0267532 A1
(43) Pub. Date: Sep. 24, 2015

(54) Evaluation of Downhole Electric Components by Monitoring Umbilical Health and Operation

(71) Applicant: Halliburton Energy Services, Inc., Houston, TX (US)

(72) Inventors: Michael Linley FRIPP, Carrollton, TX (US); Jason Dykstra, Spring, TX (US); Fanping Bu, The Woodlands, TX (US)

(21) Appl. No.: 14/727,930

(22) Filed: Jun. 2, 2015

Related U.S. Application Data
(63) Continuation of application No. 14/339,167, filed on Jul. 23, 2014.
Application No. 14/339,167 is a continuation of application No. PCT/US2013/061442, filed on Sep. 24, 2013.

(51) Int. Cl. E21B 47/12; G01R 31/08; E21B 47/09

(52) U.S. Cl. CPC E21B 47/122; E21B 47/09; G01R 31/08

(57) ABSTRACT

A method for monitoring a condition of a downhole system, the method comprising: delivering an electric signal to a downhole electric device via a downhole power transmission cable from a signal generator; receiving an electric response signal from the downhole power transmission cable; comparing the electric signal to the electric response signal to determine the location of a defect in the downhole system; and predicting a type of the defect based on said location, wherein the electric signal comprises one or more voltage pulses.

### RELATED APPLICATIONS

This application is a continuation application of pending U.S. application Ser. No. 14/339,167, filed Jul. 23, 2014 as a national stage application claiming priority to PCT Application No. PCT/US2013/061442, filed on Sep. 24, 2013.

### FIELD OF THE INVENTION

The present disclosure relates generally to systems and methods for monitoring the condition of a cable, or the operating condition of an electrically-powered, downhole tool based on feedback received from a power transmission cable.

### DESCRIPTION OF RELATED ART

Wells are drilled at various depths to access and produce oil, gas, minerals, and other naturally-occurring deposits from subterranean geological formations. The drilling of a well is typically accomplished with a drill bit that is rotated within the well to advance the well by removing topsoil, sand, clay, limestone, calcites, dolomites, or other materials.

After drilling, the well is typically completed through a number of additional tasks that may include installing casing through the wellbore and perforating the casing in regions of the formation that are expected to produce hydrocarbons, and by inserting additional tools that may enhance the performance of the well. Such additional tools may assist the extraction of fluids from the wellbore or inject fluids from the surface into the geological formation surrounding the wellbore. To that end, depending on the conditions and operating characteristics of the well and formation, a variety of tubing completion assemblies may be used in the completion tool string. In addition, to provide flexibility and safety controls, certain equipment is included in the completion tool string.

In wells that contain heavy oil, for example, an artificial lift system may be deployed to assist the oil to reach the surface. Such an artificial lift system may include an electric submersible pump that augments the flow of fluid from the formation toward the surface of the well. The electric submersible pump (sometimes referred to as an “ESP”) may be powered by an electrical power cable, or “umbilical cable”, that supplies power to the pump from a power source located at the surface of the well. In such systems, a well operator may take any number of steps to ensure that the electric submersible pump continues to receive power and operate efficiently downhole, and may also take steps to monitor the condition of devices and tools in the production tool string to ensure that the well operates efficiently.

### BRIEF DESCRIPTION OF THE DRAWINGS

FIG. 1 illustrates a schematic view of a well in which a system is deployed for determining the health of a power transmission cable that supplies power to a downhole electric tool, such as an electric submersible pump;

FIG. 2 depicts a front, detail view of a coupling between the power transmission cable and the downhole electric tool of FIG. 1;

FIG. 3 is a graph showing partially reflected signals resulting from impedance mismatches between the downhole electric tool of FIG. 1 and a power source at the surface of the well;

FIG. 4 depicts an approximation of the power transmission cable of FIG. 1 as a combination of circuit elements;

FIG. 5 shows a graph, in the time domain, of current and voltage ratios derived from the input voltage and current of the power source described with regard to FIG. 3 and the input voltage and current received at the downhole electric tool; and

FIG. 6 shows a graph, in the frequency domain, showing a passive analysis of electric signals observed on the power transmission cable of FIG. 1.

### DETAILED DESCRIPTION OF ILLUSTRATIVE EMBODIMENTS

In the following detailed description of the illustrative embodiments, reference is made to the accompanying drawings that form a part hereof. These embodiments are described in sufficient detail to enable those skilled in the art to practice the invention, and it is understood that other embodiments may be utilized and that logical structural, mechanical, electrical, and chemical changes may be made without departing from the spirit or scope of the invention. To avoid detail not necessary to enable those skilled in the art to practice the embodiments described herein, the description may omit certain information known to those skilled in the art. The following detailed description is, therefore, not to be taken in a limiting sense, and the scope of the illustrative embodiments is defined only by the appended claims.

During the operation of a well that includes an electric submersible pump or similar downhole electric tool that receives electric power from a surface-based power source, it may be beneficial to collect data relating to the health of the tool and the power transmission cable that supplies power to the downhole electric tool. The power transmission cable may be an insulated conductive cable having one or more insulated, conductive elements. The systems and methods described herein provide efficient mechanisms for monitoring the health of the transmission cable and downhole electric tool without requiring the insertion of voluminous additional equipment into the wellbore by analyzing the electrical properties of, and properties of signals propagated on, the transmission cable.

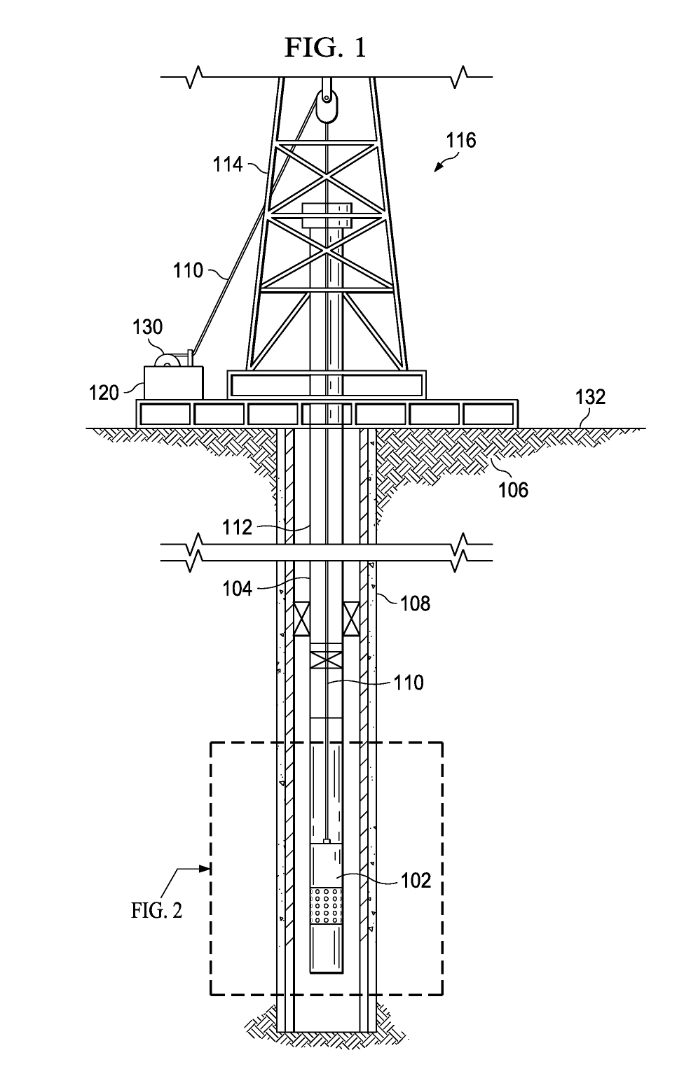

FIG. 1 shows an example of a wellbore operating environment. The operating environment includes a rig 116 atop the surface 132 of a well. Beneath the drilling rig 116 is a wellbore 108 formed within a geological formation 106 that is expected to produce hydrocarbons. The wellbore 108 may be formed in the geological formation 106 using a drill string that includes a drill bit to remove material from the geological formation 106. It is noted that while the wellbore 108 is shown as being near-vertical, the wellbore 108 may be formed at any suitable angle to reach a hydrocarbon-rich portion of the geological formation 106. As such, in an embodiment, the wellbore 108 may follow a vertical, partially vertical, angled, or even partially horizontal path through the geological formation 106.

Following or during formation of the wellbore 108, a tool string 112 may be deployed that includes tools for use in the wellbore 108 to operate and maintain the well. For example, the tool string 112 may include an artificial lift system to assist fluids from the geological formation to reach the surface 132 of the well. As discussed above, such an artificial lift system may include an electric submersible pump that receives power from the surface 132 from a power transmission cable, or “umbilical cable.” In such systems, a well operator may monitor the condition of the well and components of the production tool string to ensure that the well operates efficiently. For example, the well operator may monitor the power transmission cable, pump, or other components connected thereto to verify that power is being effectively transferred to the pump to ensure that the pump provides the desired amount of lift in the wellbore, and to ensure that there are no planned outages of an operating well that includes such an artificial lift system.

A typical electric submersible pump configuration may include one or more staged centrifugal pump sections that are tuned to the production characteristics and wellbore characteristics of a well. In some embodiments, an electric submersible pump may be formed by two or more independent electric submersible pumps coupled together in series for redundancy and augmented flow. Other electric components, such as logging equipment, may also include in the tool string to enhance well operations.

Referring again to FIG. 1, for example, the tool string 112 may include electrical components such as an electric submersible pump, or other electrically powered, downhole devices. Here, a downhole electric tool 102 is shown in schematic form. The downhole electric tool 102 may be an electric submersible pump or any other downhole electric tool that operates in the wellbore 108. The downhole electric tool 102 is coupled to a power source at the surface 132 by a cable 110, which may also be referred to as an umbilical cable or power transmission cable. The cable 110 extends to the surface 132 where it is coupled to a power source and a controller. In the embodiment of FIG. 1, the surface controller 120 provides the functionality of both a power source and a controller relative to the downhole electric tool 102. The surface controller may also include a signal generator, impedance mismatch detector, and a signal analyzer.

In addition to use in artificial lift systems, the downhole electric tool 102 may be lowered into the wellbore 108 for a variety of procedures, including drilling procedures, completion procedures, and treatment procedures through the lifecycle of the well.

In FIG. 1, the downhole electric tool 102 is deployed from a drilling rig 116 that includes a derrick 109 and a rig floor 111. The tool string 112 extends downward through the rig floor 111 into the wellbore 108 and formation. The drilling rig 116 may also include a motorized winch 130 and other equipment for extending the tool string 112 into the wellbore 108, retrieving the tool string 112 from the wellbore 108, and positioning the tool string 112 at a selected depth within the wellbore 108. While the operating environment shown in FIG. 1 relates to a stationary, land-based drilling rig 116 for raising, lowering and setting the tool string 112, in alternative embodiments, mobile rigs, wellbore servicing units (such as coiled tubing units), and the like may be used to lower the tool string 112. Further, while the operating environment is generally discussed as relating to a land-based well, the systems and methods described herein may instead be operated in subsea well configurations accessed by a fixed or floating platform.

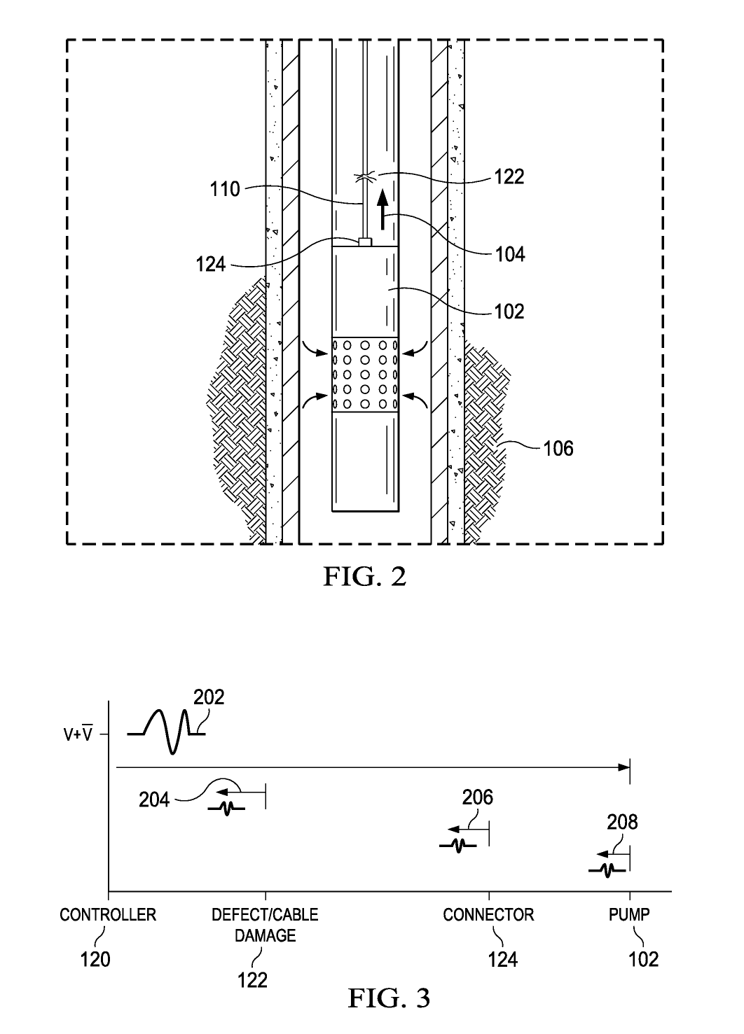

At some time after deployment of the downhole electric tool 102, equipment associated with the downhole electric tool 102 may become damaged or break, resulting in reduced efficiency or inoperability of the downhole electric tool 102. For example, the power transmission cable 110 may become frayed, kinked, or otherwise damaged to form a defect 122, as shown in FIG. 2. In an embodiment in which the power transmission cable 110 is an insulated cable, the defect 122 may be a puncture, worn region, or other damage to the insulation. In an embodiment, the downhole electric tool 102 receives power from the power transmission cable 110 via a connector 124 that couples the downhole electric tool 102 to the power transmission cable 110, and the defect may be a damaged or degraded connector or connector interface.

To detect such defects or degradation, the health of the power transmission cable 110 and associated components that receive power from a surface-based power source may be monitored by the surface controller 120. As such, the surface controller 120 may include diagnostic components, such as a signal generator and a signal analyzer. In addition, the signal analyzer may be operable to function as an impedance mismatch detector.

In an embodiment, the surface controller 120, power transmission cable 110, connector 124, and downhole electric tool 102 are designed to have matching impedances to maximize the power transfer from the surface controller 120 to the downhole electric tool 102 and to minimize power reflections from the downhole electric tool 102 back toward the power source. In the aforementioned system, the power supply of the surface controller 120 may be viewed as having a fixed output impedance, and the maximum possible power is delivered from the power supply to the downhole electric tool 102 when the impedance of the downhole electric tool 102 is equal to the complex conjugate of the impedance of the power supply. To match the impedances of the various components, any number of devices may be included within the system between the power supply and the downhole electric tool 102. In this regard, engineers may use a combination of transformers, resistors, inductors, capacitors and transmission lines to vary impedances. These passive (and active) impedance-matching devices may be optimized for different applications and may also include baluns, antenna tuners (sometimes called ATUs or roller-coasters, because of their appearance), acoustic horns, matching networks, and terminators.

Adjusting the impedance of the system to cause equivalence between the impedance of the power supply and the impedance of the downhole electric tool 102 may be referred to as “impedance matching.” Conversely, defects or design flaws in the system that result in the non-equivalence of the impedance of the downhole electric tool 102 and the impedance of the power supply may be referred to as “impedance mismatches”.

Each impedance mismatch, correspondingly, may result in a reflected signal from the mismatch source to the power supply. Thus, by including a signal generator, an impedance mismatch detector, and a signal analyzer within the surface controller 120, the surface controller 120 may be made capable of detecting defects 122 in a down-hole electrical system that includes the power transmission cable 110, connector 124, the downhole electric tool 102, and other elements connected thereto. To detect such a defect, the signal generator of the surface controller 120 generates an electric signal to the downhole electric tool 102. In an embodiment, the electric signal is a voltage pulse that is transmitted on top of the normal voltage applied to the power transmission cable 110 to power the downhole electric tool 102. The voltage pulse will be partially reflected by slight impedance mismatches throughout the system at locations where elements are joined together or where defects in the system exist.

For example, very minor imperfections in the fabrication of the system and its components will result in a slight impedance mismatch at expected locations, including at the interface between the surface controller 120 and the power transmission cable 110, the interface between the power transmission cable 110 and the connector 124, and at the downhole electric tool 102. While these impedance mismatches are generally expected, additional impedance mismatches may indicate a defect in the power transmission cable 110 or other components of the system.

In an embodiment, the surface controller 120 generates a series of voltage pulses and the impedance mismatch detector included in the surface controller 120 detects and maps the locations and magnitudes of expected impedance mismatches. For example, FIG. 3 shows that a voltage pulse 202 is added to an operating voltage that powers a downhole electric tool after being transmitted along a power transmission cable. Echoes, or impedance mismatches, are generated at various points between the surface controller 120 and downhole electric tool 102. As noted above, such expected impedance mismatches include an impedance mismatch generated at the connector 206 and an impedance mismatch generated at the downhole electric tool 208. When subsequent voltage pulses are applied to the system, impedance mismatches detected by the impedance mismatch detector may be analyzed and compared to the map of expected impedance mismatches. In an embodiment, detected impedance mismatches that do not correspond to expected impedance mismatches may be taken to indicate a defect in the system. As shown in FIG. 3, an unexpected impedance mismatch is also generated by a defect in the power transmission cable 204.

For example, in analyzing the power transmission cable 204′s response to a voltage pulse to monitor impedance mismatch, the magnitude of the reflected wave, V_{ref}, will depend on the magnitude of the incoming wave, V, as well as the impedance mismatch at the downhole location. The impedance mismatch at the downhole location depends on the impedance at the location, Z, as well as on the natural impedance of the transmission line, Zₒ. The magnitude of the reflection can be approximated as:

V_{ref}=V*(Z−Zₒ)/(Z+Zₒ).

The impedance at the downhole location will range from zero if it is a short circuit to infinity if it is an open circuit or a break in the wire. In most cases, the impedance will be a value between zero and infinity. The impedance is typically a complex number with a real part corresponding to the resistance and an imaginary part corresponding to the inductance. The impedance can be constant or it can vary with the transmission frequency.

The detected impedance mismatches may be received at the surface controller 120 in the form of a response signal. In an embodiment, the time between the receipt of the response signal at the surface controller 120 and the transmission of the signal or voltage pulse that resulted in the response signal may indicate the location of the defect 122. This location information may also provide some indication as to the type of defect being detected because certain defects may be more likely to occur at different locations along the power transmission cable than others. For example, suspected defects in the power transmission cable 110 of the downhole electric tool 102 may be a fray, a crimp, a kink, fluid intrusion, damaged insulation, or another defect. Defects calculated to be at or after the end of the power transmission cable may consist of a damaged connector 124, or a malfunction in the downhole electric tool 102, such as a motor malfunction.

In an embodiment, the system may detect defects in the power transmission cable by delivering an electric signal to a downhole electric tool, such as an electric submersible pump, via a downhole cable. In such an embodiment, the voltage and current at the power supply are compared to the voltage and current at the downhole electric tool. The voltage drop or change in current will be indicative of an expected voltage drop due to ohmic losses or resistance and the power transmission cable and current loss will be indicative of leakage through the power transmission cable's insulation. The time rate of change of the voltage or current loss may also be indicative of the health of the power transmission cable and as such, determinations as to the health of the power transmission cable may be made by analyzing the voltage loss and current loss in time domain and frequency domain analyses. In the frequency domain, the electrical noise in the voltage signal generated by the power transmission cable and by the downhole electric tool are analyzed. As the health of the power transmission cable degrades, the electrical noise can increase depending on the type of degradation. For example, arcing through the insulation or across a connector will create cable noise that indicates the aggregation of the cable or connector. As such, noise peaks may also be observed to indicate

The electric signal may be delivered by a signal generator coupled to or included in a surface controller. The electric signal may be analyzed using a signal processor coupled to the power transmission cable to observe the response signal that results from the electric signal. The electric signal may be an initial voltage or initial current, and the response signal may be a voltage or current, respectively, received at the tool. As such, the response signal may be indicative of the voltage drop between the signal generator and the downhole electric tool. In an embodiment, the response signal may instead be indicative of a change in current between the signal generator and the downhole electric tool. The system may function by comparing the electric signal to the response signal and determining the condition of the power transmission cable from the comparison. The signal may be an AC signal or a DC signal, and the signal and response signal may be analyzed in the time domain or frequency domain.

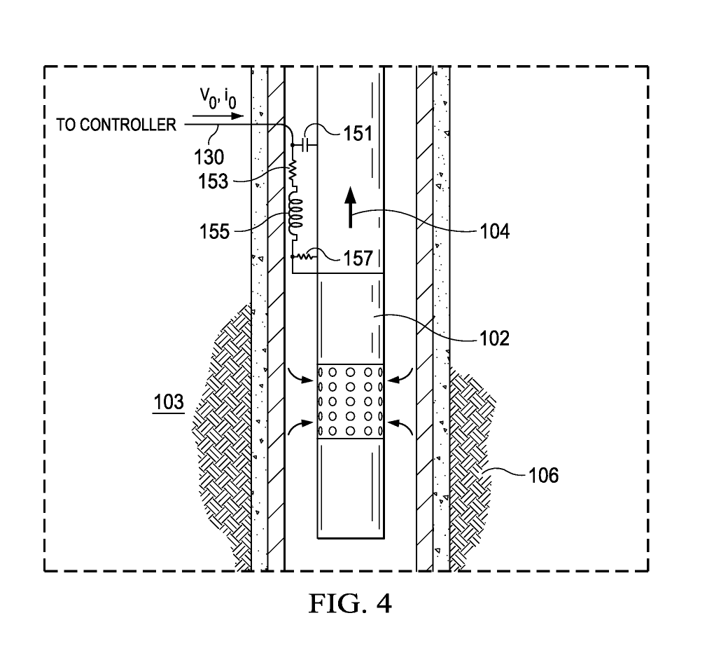

For example, defects in the power transmission cable 110 or at other points in the system may be detected using a passive analysis of the power transmission cable 110. FIG. 4 shows schematically that the power transmission cable 110 may be approximated as a circuit that includes capacitive elements 151, inductive elements 155, and resistive elements 153 and 157. In such an embodiment, defects may be detected by comparing an initial voltage (V₀) or initial current (i₀) to the voltage received at the downhole electric tool 102 (Vᵢ) or current received at the downhole electric tool 102(iᵢ), respectively.

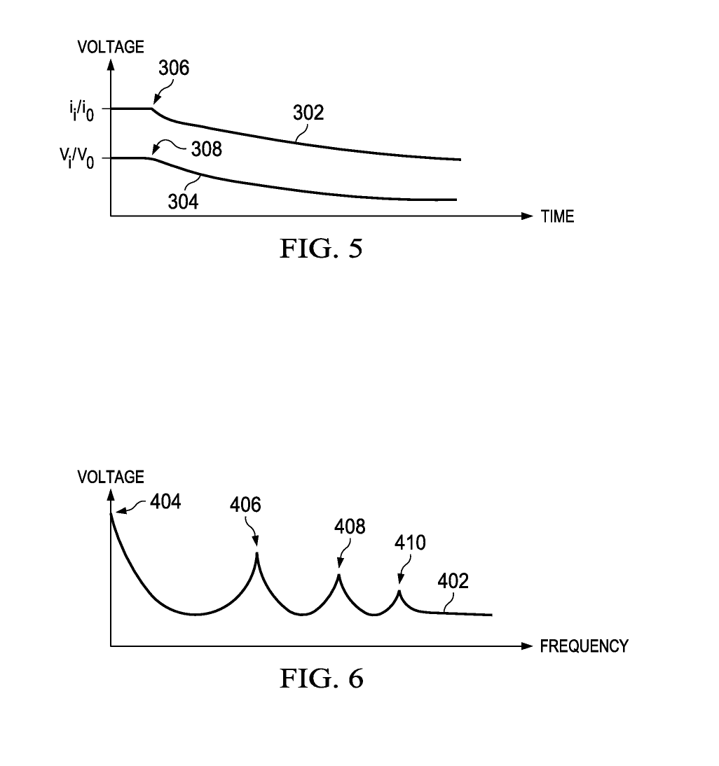

Here, a ratio of the voltage received at the downhole electric tool to the initial voltage (Vᵢ /V₀) or a ratio of the current received at the downhole electric tool to the initial current (iᵢ/i₀) may be analyzed over time to indicate the occurrence of a defect. The relative phase between the voltage and current may also be compared to indicate the occurrence of a defect. As shown in FIG. 5, for example, a first line 302 indicates the current ratio over time and a second line 304 indicates the voltage ratio over time. Here, a first inflection point 306 indicates an abrupt change in the current ratio corresponding to an unexpected decrease in the current received at the downhole electric tool. This first inflection point 306 evidences that loss is occurring between the power supply and the tool. Similarly, a second inflection point 308 in the voltage curve of the second line 304 indicates a drop in the voltage received at the tool, which may also evidence a decay in the ability of the power transmission cable to convey power to the tool.

FIG. 6 shows a frequency domain analysis that may also be used to determine the existence of a defect in a power transmission cable, connector or downhole electric tool. This type of passive analysis can be accomplished by looking at the electrical noise generated by the power transmission cable and by the downhole electric tool. As the health of the components degrade, the electric noise can increase depending on the type of degradation. For example, arcing through the installation of the cable would create cable noise. As such, FIG. 6 shows an approximation of a voltage detected at the surface controller. Here, a first voltage peak 404 corresponds to the DC signal of a DC power supply and a second voltage peak 406 corresponds to an AC power supply, which may be provided to the system as an alternative to a DC power supply. A third voltage peak 408 is associated with noise generated by the downhole electric tool, and a fourth voltage peak 410 is generated by the power transmission cable. Since noise is generally not expected to be seen in significant magnitudes along the power transmission cable, the detection of such noise may indicate a defect in the installation of the power transmission cable or other source of arcing along the cable.

Several mathematical algorithms that can be used to determine the existence of a defect by analyzing the noise created in the electrical cable. In an embodiment, a Fourier transform is used to detect defects in the system when electrical noise is steady, as described with regard to FIG. 6. Here, a short-time Fourier transform or alternatively a spectrogram can be used to see a signal that indicates changes in impedance over time. In addition, a non-periodic and/or non-stationary signal may be analyzed using a wavelet transform. It is also possible to observe the spectral changes in electrical noise as a function of time. The Fourier transform analysis described above is generally accomplished by analyzing a window of data corresponding to a fixed time frame. In an embodiment, an operator may analyze how the noise is changing as a function of time by looking at different Fourier transform analyses from prior sets of windowed data, or prior time frames. This data may be applied to give an indication of how the impedance of the cable and system are changing with time, and allow an operator to predict the life expectancy of the cable or other system elements using a curve fitting algorithm with an expected break down rate, or a learning algorithm such as a neural network.

Even though only a few specific examples are provided for the systems that may be employed to measure the deflection of a drill string or a drill collar adjacent a drill bit, it is noted that any combination of embodiments discussed above of illustrative drilling optimization collars and sensor configurations is suitable for use with the systems and methods described herein.

The drilling optimization collar and related systems and methods may be described using the following examples:

### Example 1

A method for monitoring the health of a downhole cable, the method comprising:

delivering an electric signal to a downhole electric device via a downhole cable from a signal generator;

receiving an electric response signal from the downhole cable; and

comparing the electric signal to the response signal to determine a condition of the power transmission cable,

wherein the electric signal comprises one or more voltage pulses.

### Example 2

The method of example 1, wherein response signal comprises one or more impedance mismatches resulting from a defect in the downhole cable.

### Example 3

The method of example 2, further comprising determining the existence and location of the defect based on the electric response signal.

### Example 4

The method of examples 2-3, wherein the defect is selected from the group consisting of a crimp, a kink, fluid intrusion, and insulation damage.

### Example 5

The system of examples 2-3, wherein the defect comprises a poorly performing connector.

### Example 6

The system of examples 2-3, wherein the downhole electric device comprises a motor, and wherein the defect comprises a defect in the operation of the motor.

### Example 7

The system of examples 1-7, wherein the one or more voltage pulses is a series of voltage pulses.

### Example 8

A method for monitoring the health of a downhole cable, the method comprising:

delivering an electric signal to a downhole electric device via a downhole cable from a signal generator;

receiving an electric response signal from the downhole cable; and

comparing the electric signal to the response signal to determine a condition of the power transmission cable,

wherein delivering an electric signal comprises delivering an A/C current signal.

### Example 9

The method of example 9, wherein the response signal comprises a signal indicative of the voltage drop between the signal generator and the electric device.

### Example 10

The method of examples 9-10, further comprising monitoring the time rate of change of voltage drop between the signal generator and the electric device.

### Example 11

The method of examples 9-11, wherein the response signal comprises a signal indicative of the change in current between the signal generator and the electric device.

### Example 12

The method of examples 9-12, further comprising monitoring the time rate of change of the current between the signal generator and the electric device.

### Example 13

A system for monitoring a downhole cable, the system comprising:

a controller having a signal generator, a signal receiver, and a signal processor;

a downhole electric device; and

a power transmission cable coupled to the controller and the downhole electric device;

wherein:

the signal generator is operable to generate an electric signal to the downhole electric device via the power transmission cable,

the signal receiver is operable to receive a response signal from the power transmission cable, and

the signal processor is operable to determine a condition of the power transmission cable based on a comparison of the electric signal to the response signal.

### Example 14

The system of example 14, wherein the response signal is an impedance mismatch resulting from a defect in the power transmission cable.

### Example 15

The system of example 15, wherein the defect is selected from the group consisting of a crimp, a kink, fluid intrusion, and insulation damage.

### Example 16

The system of example 15, wherein the defect comprises a poorly performing connector.

### Example 17

The system of example 15, wherein downhole electric device comprises a motor, and wherein the defect comprises a defect in the operation of the motor.

### Example 18

The system of example 14-17, wherein the signal processor is operable to determine the location of the defect based on the impedance mismatch.

### Example 19

The system of example 14-19, wherein the electric signal comprises a voltage pulse.

### Example 20

The system of example 14-20, wherein the processor is operable to determine a source of degradation based on the response signal.

It should be apparent from the foregoing that an invention having significant advantages has been provided. While the invention is shown in only a few of its forms, it is not limited to only these embodiments but is susceptible to various changes and modifications without departing from the spirit thereof.

We claim:

1. A method for monitoring a condition of a downhole system, the method comprising:
delivering an electric signal to a downhole electric device via a downhole power transmission cable from a signal generator;
receiving an electric response signal from the downhole power transmission cable;
comparing the electric signal to the electric response signal to determine the location of a defect in the downhole system; and
predicting a type of the defect based on said location,
wherein the electric signal comprises one or more voltage pulses.

2. The method of claim 1, wherein the defect is selected from the group consisting of a crimp, a kink, fluid intrusion, and insulation damage in the downhole power transmission cable.

3. The method of claim 1, wherein the defect comprises a connector defect.

4. The method of claim 1, wherein the downhole electric device comprises a motor, and wherein the defect comprises a defect in the operation of the motor.

5. The method of claim 1, wherein the one or more voltage pulses is a series of voltage pulses.

6. The method of claim 1, wherein said predicting comprises:
predicting that the defect is of a first type if said location is in the power transmission cable; and
predicting that the defect is of a second type if said location is after an end of the power transmission cable.

7. A method for monitoring the health of a downhole electrical system, the method comprising:
delivering an electric signal to a downhole electric device via a downhole power transmission cable from a signal generator;
receiving an electric response signal from the downhole power transmission cable; and
using the electric response signal to monitor a rate of change of a voltage drop between the signal generator and the downhole electric device,
wherein delivering the electric signal comprises delivering an alternating current signal.

8. The method of claim 7, wherein the electric response signal indicates a change in current between the signal generator and the downhole electric device.

9. The method of claim 8, further comprising monitoring the rate of change of the current between the signal generator and the downhole electric device.

10. A system for monitoring a downhole cable, the system comprising:
a controller having a signal generator, a signal receiver, and a signal processor;
a downhole electric device; and
a power transmission cable coupled to the controller and the downhole electric device, wherein:
the signal generator is operable to generate an electric signal to the downhole electric device via the power transmission cable,
the signal receiver is operable to receive a response signal from the power transmission cable, and
the signal processor is operable to determine a condition of the power transmission cable based on a time-domain analysis of the ratio of a voltage at the downhole electric device to a voltage at the controller using the electric signal and the response signal.

11. The system of claim 10, wherein the response signal indicates an impedance mismatch resulting from a defect in the power transmission cable.

12. The system of claim 11, wherein the defect is selected from the group consisting of a crimp, a kink, fluid intrusion, and insulation damage.

13. The system of claim 11, wherein the defect comprises a connector defect.

14. The system of claim 11, wherein the downhole electric device comprises a motor, and wherein the defect comprises a defect in the operation of the motor.

15. The system of claim 11, wherein the signal processor is operable to determine the location of the defect based on the impedance mismatch.

16. The system of claim 10, wherein the electric signal comprises a series of voltage pulses.

17. The system of claim 10, wherein the signal processor is operable to determine a source of degradation based on the response signal.
